(19) United States
(12) Patent Application Publication
(10) Pub. No.: US 2011/0235419 A1
(43) Pub. Date: Sep. 29, 2011

(54) NON-VOLATILE SEMICONDUCTOR STORAGE DEVICE

(75) Inventors: Tetsuya ISHIMARU, Tokyo (JP); Yasuhiro Shimamoto, Tokorozawa (JP); Hideo Kasai, Kanagawa (JP); Yutaka Okuyama, Kokubunji (JP); Tsuyoshi Arigane, Akishima (JP)

(73) Assignee: RENESAS ELECTRONICS CORPORATION

(21) Appl. No.: 13/073,988

(22) Filed: Mar. 28, 2011

(30) Foreign Application Priority Data
Mar. 29, 2010 (JP) JP2010-074065

(51) Int. Cl. G11C 16/04

(52) U.S. Cl. 365/185.15; 365/185.27

(57) ABSTRACT

In a split gate MONOS memory which carries out rewrite by hot carrier injection, retention characteristics are improved. A select gate electrode of a memory cell is connected to a select gate line, and a memory gate electrode is connected to a memory gate line. A drain region is connected to a bit line, and a source region is connected to a source line. Furthermore, a well line is connected to a p type well region in which the memory cell is formed. When write to the memory cell is to be carried out, write by a source side injection method is carried out while applying a negative voltage to the p type well region via the well line.

### CROSS-REFERENCE TO RELATED APPLICATION

The present application claims priority from Japanese Patent Application No. 2010-074065 filed on Mar. 29, 2010, the content of which is hereby incorporated by reference into this application.

### TECHNICAL FIELD OF THE INVENTION

The present invention relates to a non-volatile semiconductor storage device, and more particularly to the technique effectively applied to a non-volatile semiconductor storage device having a split gate MONOS (Metal Oxide Nitride Oxide Semiconductor) memory.

### BACKGROUND OF THE INVENTION

Electrically writable/erasable non-volatile semiconductor storage devices (non-volatile semiconductor memories) typified by a flash memory have been widely used today as data-storing storage devices of memory cards and program-storing memories of microcontrollers.

For example, when a non-volatile semiconductor memory is used as a program-storing memory of a microcontroller, since the program can be rewritten even after development or shipment of a device on which the microcomputer is mounted, advantages such as significant reduction in the device development period and prompt response to bug occurrence and specification changes can be achieved. Therefore, the microcontroller on which a non-volatile semiconductor memory is mounted has been used for various purposes in recent years.

Examples of the non-volatile semiconductor memory to be mounted on a microcontroller include a split gate MONOS memory. The split gate memory refers to a type of memory in which one memory cell has two gate electrodes (memory gate and select gate). MONOS refers to a non-volatile memory in which information is stored by accumulating electric charge in a trapping insulating film such as a silicon nitride film.

The split gate MONOS memory can carry out both a writing operation and an erasing operation by hot carrier injection as described in, for example, U.S. Pat. No. 5,969,383 (Patent-Document 1). Further, the writing operation can be carried out also by hot electron injection according to a source side injection (SSI) writing method. For example, IEEE International Electron Devices Meeting Technical Digest 1989, pp. 603 to 606 (Non-Patent Document 1) describes that the electrons flowing in a channel are accelerated by the high electric field of the channel region between two gate electrodes and efficiently injected into a silicon nitride film serving as a charge accumulation region.

### SUMMARY OF THE INVENTION

FIG. 13 is a cross-sectional view showing the memory cell structure of a split gate MONOS memory. Note that an n channel memory cell will be described here.

The memory cell includes: an ONO film 10 made up of a silicon nitride film 12 for accumulating electric charge and two layers of silicon oxide films 11 and 13 sandwiching the silicon nitride film 12; a memory gate electrode 16 and a select gate electrode 17 made of conductive films such as n type polycrystalline silicon films; a gate insulating film 14 made of a silicon oxide film formed below the select gate electrode 17; and a source region 15S and a drain region 15D made of semiconductor regions into which an n type impurity is introduced. The source region 15S and the drain region 15D of the memory cell are formed in a p type well region 21 formed in a semiconductor substrate 20 made of, for example, p type single-crystal silicon.

In the following descriptions, a MIS transistor (MISFET: Metal Insulator Semiconductor Field Effect Transistor) having the memory gate electrode 16 is referred to as a memory transistor, and a MIS transistor having the select gate electrode 17 is referred to as a select transistor.

In the case of a conventional split gate MONOS memory which carries out a rewriting operation by a SSI writing method and a Band-To-Band Tunneling (BTBT) erasing method, electrons are injected from the drain region 15D side to the silicon nitride film 12 in the writing. On the other hand, holes are injected from the source region 15S side, which is on the opposite side of the writing, to the silicon nitride film 12 in the erasing. In other words, the electron injection in the writing and the hole injection in the erasing are carried out from the mutually opposite sides of the channel direction.

Therefore, in the split gate MONOS memory which carries out the rewriting operation by the SSI writing method and the BTBT erasing method, there is a problem that the write electron distribution and the erase hole distribution in the silicon nitride film 12 are shifted from each other. When the electron distribution and the hole distribution are shifted from each other, in the case where the rewriting operations are carried out by repeating the writing and erasing, the electrons and holes are failed to be eliminated and are gradually increased at the shifting position along with the increase in the number of times of rewriting, and pair annihilation of the electrons and holes occurs in the silicon nitride film 12 during retention, thereby deteriorating the retention characteristics.

An object of the present invention is to provide the technique for improving the retention characteristics in a split gate MONOS memory which carries out the rewriting operation by hot carrier injection.

The above and other objects and novel characteristics of the present invention will be apparent from the description of the present specification and the accompanying drawings.

The following is a brief description of an outline of the typical invention disclosed in the present application.

A non-volatile semiconductor storage device includes: a plurality of non-volatile memory cells formed in a first region of a semiconductor substrate; and a drive circuit formed in a second region of the semiconductor substrate, and each of the plurality of memory cells has: (a) first and second semiconductor regions formed in the semiconductor substrate; (b) a first conductive layer and a second conductive layer formed on the semiconductor substrate between the first and second semiconductor regions, the first conductive layer being positioned on a first semiconductor region side, the second conductive layer being positioned on a second semiconductor region side; (c) a first insulating film formed between the first conductive layer and the semiconductor substrate; and (d) a charge accumulating region made of a second insulating film formed between the second conductive layer and the semiconductor substrate, the drive circuit controls voltages applied to the first region of the semiconductor substrate, the first semiconductor region, the second semiconductor region, the first conductive layer and the second conductive layer, thereby carrying out a writing operation by hot electron injection using a source side injection method and carrying out an erasing operation by a hot hole injection method utilizing a band-to-band tunneling phenomenon, and a negative voltage is applied to the first region of the semiconductor substrate in the writing operation.

The effects obtained by typical embodiments of the invention disclosed in the present application will be briefly described below.

The retention characteristics can be improved without deteriorating the disturb resistance of a non-volatile memory cell which carries out a rewriting operation by hot carrier injection.

### BRIEF DESCRIPTIONS OF THE DRAWINGS

FIG. 1 is a circuit block diagram of a microcontroller including a flash memory according to a first embodiment of the present invention;

FIG. 2 is a cross-sectional view showing another example of a split gate MONOS memory according to the first embodiment of the present invention;

FIG. 3 is an equivalent circuit diagram showing voltage application conditions in a writing operation of the split gate MONOS memory according to the first embodiment of the present invention;

FIG. 4 is an equivalent circuit diagram showing an example of the circuit configuration which realizes the writing/erasing operations of a constant channel current;

FIG. 5 is a graph showing the simulation results of the width of an electron injection region in the channel length direction in the case where a negative voltage is applied to a p type well region in the writing and the case where no voltage is applied thereto;

FIG. 6 is a graph showing the amount of the change in the threshold voltage in the retention in an erase state obtained after rewrite is carried out in the case where a negative voltage is applied to the p type well region in the writing and the case where no voltage is applied thereto;

FIG. 7 is a timing chart of the voltage application in a writing operation of the split gate MONOS memory according to the first embodiment of the present invention;

FIG. 8 is an equivalent circuit diagram showing voltage application conditions in an erasing operation of the split gate MONOS memory according to the first embodiment of the present invention;

FIG. 9 is a graph showing the relation between the voltage applied to the p type well region in the erasing and the erasing time standardized by the erasing time at the point when the voltage applied to the p type well region is 0 V;

FIG. 10 is a timing chart of the voltage application in the erasing operation of the split gate MONOS memory according to the first embodiment of the present invention;

FIG. 11 is an equivalent circuit diagram showing the voltage application conditions in a reading operation of the split gate MONOS memory according to the first embodiment of the present invention;

FIG. 12 is a block diagram schematically showing a semiconductor chip formed by integrating a plurality of non-volatile memory modules and others according to a second embodiment of the present invention; and

FIG. 13 is a cross-sectional view showing the memory cell structure of a split gate MONOS memory.

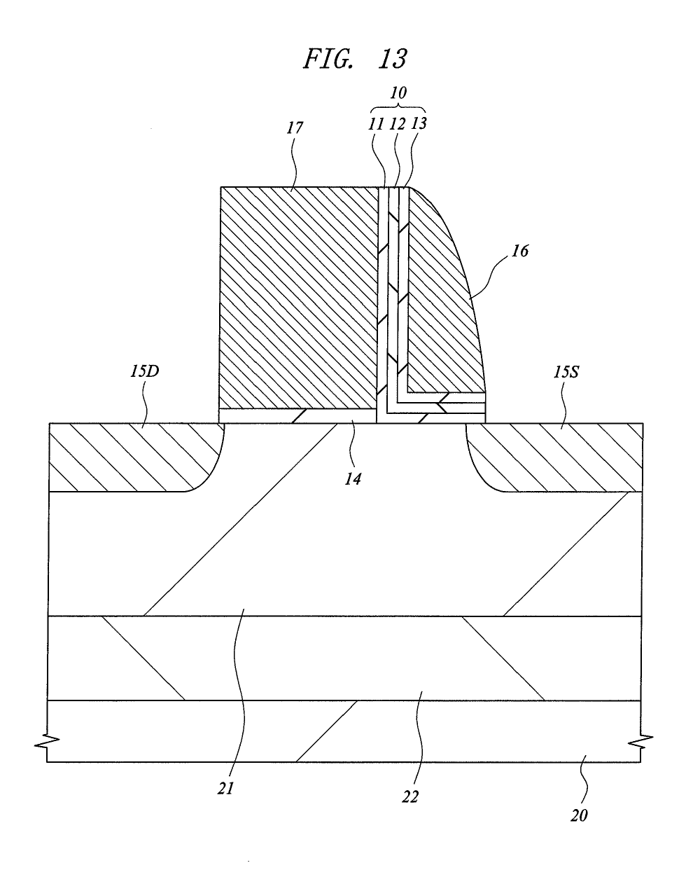

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiments, and the repetitive description thereof will be omitted. In addition, the description of the same or similar portions is not repeated in principle unless particularly required in the following embodiments. Also, in some drawings used in the following embodiments, hatching is used even in a plan view so as to make the structure easy to see.

### First Embodiment

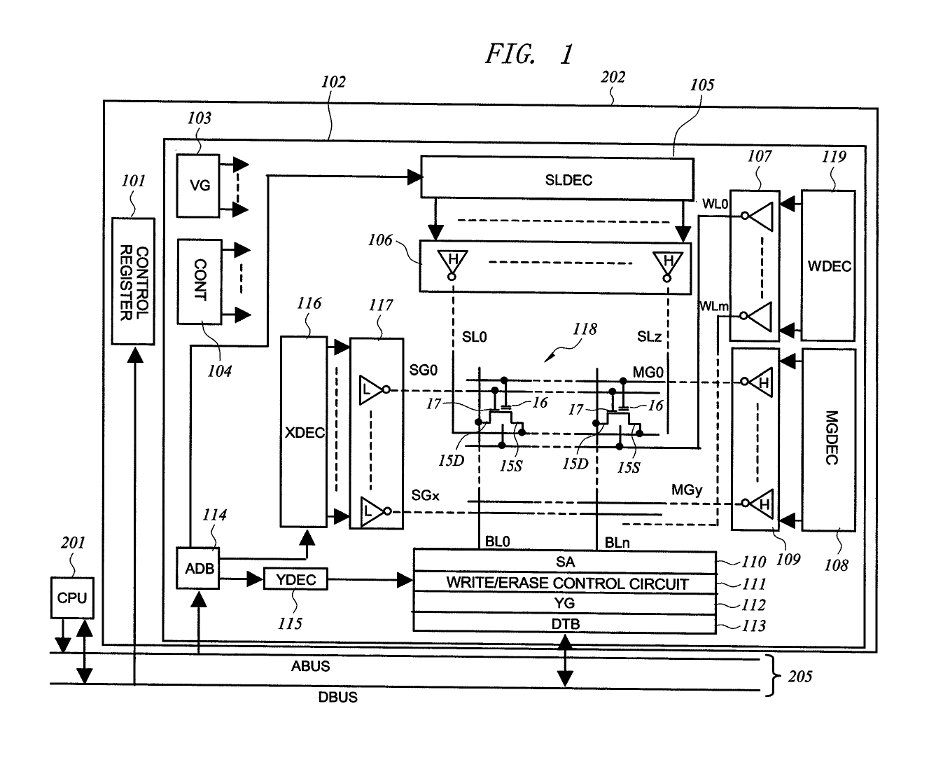

FIG. 1 is a circuit block diagram of a microcontroller including a flash memory which is an embodiment of a semiconductor storage device according to the present invention.

The microcontroller shown in FIG. 1 is not particularly limited, but is formed on a semiconductor substrate such as a single-crystal silicon substrate by publicly known semiconductor integrated circuit manufacturing techniques. A central processing unit (CPU) 201 and a flash memory 202 are coupled to each other by buses 205. The flash memory 202 stores programs or data executed by the CPU 201. The buses 205 include a data bus DBUS for transferring data and an address bus ABUS for transmitting address signals.

The flash memory 202 is not particularly limited, but includes a control register 101 and a flash memory module 102. The control register 101 is coupled to the data bus DBUS of the buses 205, and the setting of the control register is carried out via the data bus DBUS.

The flash memory module 102 is not particularly limited, but includes: a power generating circuit (VG) 103, a controller (CONT) 104, a source decoder (SLDEC) 105, a source driver 106, a well decoder (WDEC) 119, a well driver 107, a memory gate decoder (MGDEC) 108, a memory gate driver 109, a sense amplifier (SA) 110, a write/erase control circuit 111, a column gate (YG) 112, a data input/output buffer (DTB) 113, an address buffer (ADB) 114, a column address decoder (YDEC) 115, a row address decoder (XDEC) 116, a select gate driver 117 and a memory cell array 118.

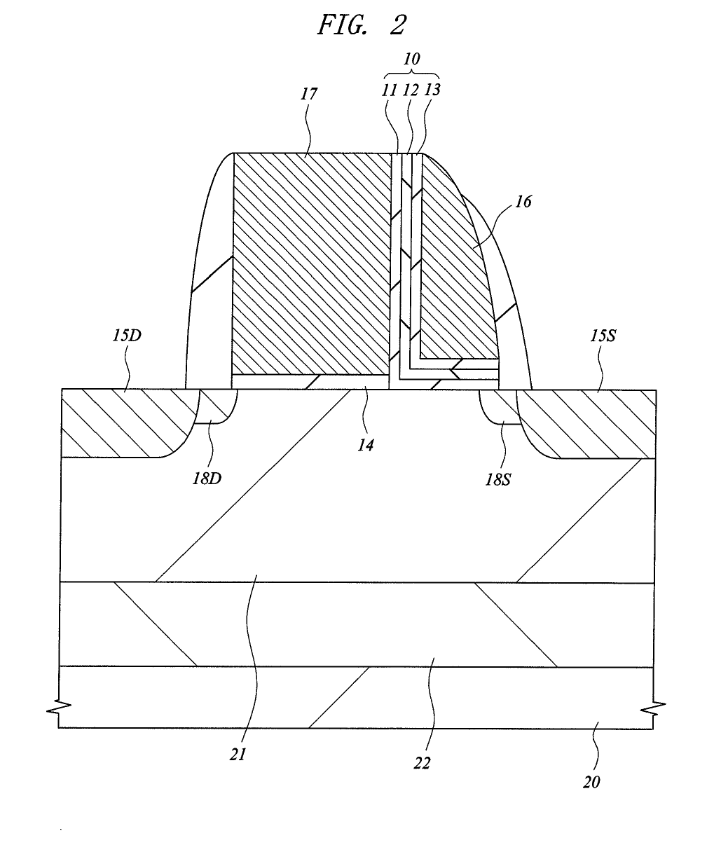

The memory cell array 118 is made up of memory cells disposed at the locations where a plurality of select gate lines (word lines) SG0 to SGx, a plurality of memory gate lines MG0 to MGy, a plurality of source lines SL0 to SLz, a plurality of bit lines BL0 to BLn and well lines WL0 to WLm mutually intersect. Each of these memory cells is a split gate MONOS memory having the structure shown in FIG. 2. The NOR type, NAND type and others can be employed for the memory cell array 118.

The operation (reading, writing, erasing and others) of the flash memory module 102 is determined when a value is set in the control register 101 from the CPU 201 via the data bus DEUS. The controller 104 changes the generated voltage of the voltage generating circuit 103 to the voltage necessary for reading, writing, erasing and others based on the above-described value of the control register 101 and controls the operation of the corresponding parts so as to supply the necessary voltages to a select gate electrode 17, a memory gate electrode 16, a source region 15S and others of the memory cell shown in FIG. 2 at appropriate timing. A negative voltage power supply is connected to the well lines WL0 to WLm so as to apply a negative voltage in the writing or the erasing.

Address information input from the address bus ABUS is saved in the address buffer 114, and the memory cells are selected based on the information by the row address decoder 116, the memory gate decoder 108, the source decoder 105 and the column address decoder 115 and reading, writing, erasing and others are carried out.

The row address decoder 116 selects the select gate driver 117 based on the input address information and controls the voltage of the select gate electrode 17. The memory gate decoder 108 selects the memory gate driver 109 based on the input address information and controls the voltage of the memory gate electrode 16. The source decoder 105 selects the source driver 106 based on the input address information and controls the voltage of the source region 15S of the memory cell.

The column address decoder 115 controls the operation of the column gate 112 and the write/erase control circuit 111 based on the input address information. The write/erase control circuit 111 latches write data in the writing and controls the electric potentials of the bit lines BL0 to BLn and the source lines SL0 to SLz in the writing and erasing.

The sense amplifier 110 amplifies and latches the read signals which appear on the bit lines BL0 to BLn. The latch data is transmitted to the column gate 112, and only the data matching the address is transmitted to the input/output buffer 113 via the column gate 112 and can be output to the data bus DBUS.

The parts of the memory cells shown in FIG. 2 are connected to the wiring shown in FIG. 1 in the following manner. The select gate electrodes 17 are connected to the corresponding select gate lines SG0 to SGx, respectively, and the memory gate electrodes 16 are connected to the corresponding memory gate lines MG0 to MGy, respectively. Also, drain regions 15D are connected to the corresponding bit lines BL0 to BLn, respectively, and source regions 15S are connected to the corresponding source lines SL0 to SLz, respectively.

The select gate lines SG0 to SGx, the memory gate lines MG0 to MGy and the source lines SL0 to SLz extend in parallel to each other. The bit lines BL0 to BLn connecting the drain regions 15D of the memory cells extend in the direction orthogonal to the select gate lines SG0, SG1 and others. The select gate lines SG0, SG1 and others may be made of the select gate electrodes 17 or may be made of other wiring connected to the select gate electrodes 17. Although not shown in the drawings, p type well regions 21 are connected to high-concentration p type impurity regions formed therein and to the corresponding well lines WL0 to WLm via contact holes connected to the high-concentration p type impurity regions. The p type well regions 21 are electrically separated from the CPU 201 and the well regions of the control circuit of the flash memory by forming n type well regions 22 for preventing electrical conduction therebetween between the semiconductor substrate 20 and the p type well regions 21. By this means, negative voltages can be applied to the p type well regions 21 in the writing or erasing operation without affecting the CPU 201 and the control circuit of the flash memory 202.

Each of the memory gate lines MG0 to MGy connecting the memory gate electrodes 16 and the source lines SL0 to SLz connecting the source regions 15S is independently laid, but the lines may be made into a shared memory gate line and source line by connecting a plurality of lines. Also, the well lines WL0 to WLm may be independently provided respectively for the select gate lines SG0 to SGx, each of the well lines may be provided for a plurality of the select gate lines SG0 to SGx or for 1 byte of memory cell, or all of the memory cells may be connected by a common well line. If all of the memory cells are connected by the common well line, the well decoder (WDEC) 119 becomes unnecessary because there is no need to select the well line. When plural lines of the wiring of the memory gate lines MG0 to MGy, the source lines SL0 to SLz, the well lines WL0 to WLm and others are mutually connected to be shared lines, the number of the high-withstand-voltage drivers which drive the lines can be reduced, and therefore, the memory cells can be more densely disposed and the chip area can be reduced. In contrast, when the wirings are independently provided, the time disturbed due to the voltage application to the well lines in the writing and erasing can be reduced.

It is desired in the memory cell shown in FIG. 2 that the threshold voltage of the select transistor is set to be higher than the threshold voltage of the memory transistor. In other words, the p type impurity concentration of the channel region of the select transistor is made higher than the p type impurity concentration of the channel region of the memory transistor. Alternatively, the n type impurity concentration of the channel region of the select transistor is made lower than the n type impurity concentration of the channel region of the memory transistor. When the threshold voltage of the select transistor is made high, the leakage current of non-selected memory cells in the reading can be reduced. Moreover, when the threshold voltage of the memory transistor is made low, the read current of the selected memory cell in the reading can be increased.

Regarding the drain region 15D, since the maximum voltage applied to this region in the operation of the memory cell is about 1.5 V, a source/drain structure of a MIS transistor presupposed to be driven at 1.5 V can be employed. For example, the drain region 15D can be made of a high-concentration n type impurity region almost equivalent to that of a MIS transistor which operates at 1.5 V. Moreover, as shown in FIG. 2, the LDD (Lightly Doped Drain) structure can be formed by providing a low-concentration n type impurity region 18D at the end portion of the drain region 15D on the select gate electrode 17 side.

On the other hand, the source region 15S is also a high-concentration n type impurity region. Moreover, as shown in FIG. 2, the LDD structure can be formed by providing a low-concentration n type impurity region 18S at the end portion of the source region 15S on the memory gate electrode 16 side. The impurity concentration of the low-concentration n type impurity region 18S has to be a concentration which is appropriate for causing BTBT. For example, the concentration is preferably about 10¹⁸ to 10²⁰/cm³, and more preferably about 10¹⁸ to 10¹⁸/cm³.

The film thicknesses of the silicon nitride film 12 below the memory gate electrode 16 and the silicon oxide films 11 and 13 below and above the silicon nitride film 12 are important elements which determine the characteristics of the memory cell. In the memory cell employing the erasing method of the present invention, hot carrier injection is utilized for both the writing and erasing, and therefore, the film thicknesses of the silicon oxide films 11 and 13 below and above the silicon nitride film 12 can be increased. For example, the film thickness of the silicon nitride film 12 is about 3 to 15 nm, the film thickness of the silicon oxide film 11 is about 3 to 6 nm, and the film thickness of the silicon oxide film 13 is about 4 to 10 nm. When the film thickness of each of the silicon oxide films 11 and 13 is set to 3 nm or more, variations in the accumulated electric charge due to the tunneling phenomenon can be suppressed.

Next, the writing, erasing and reading operations of the memory cell according to the present embodiment will be sequentially described. Herein, the injection of electrons into the silicon nitride film 12 is defined as “write”, and the injection of holes thereinto is defined as “erase”. Furthermore, in order to provide typical operating voltage conditions, the description will be given by using the memory cell formed by using so-called 0.18-micron (μm) generation process/device techniques of MISFET. More specifically, the gate length of the select transistor is 0.15 μm, and the cell operated by a 1.5 V system is used. The channel width of the memory cell is 0.25 μm.

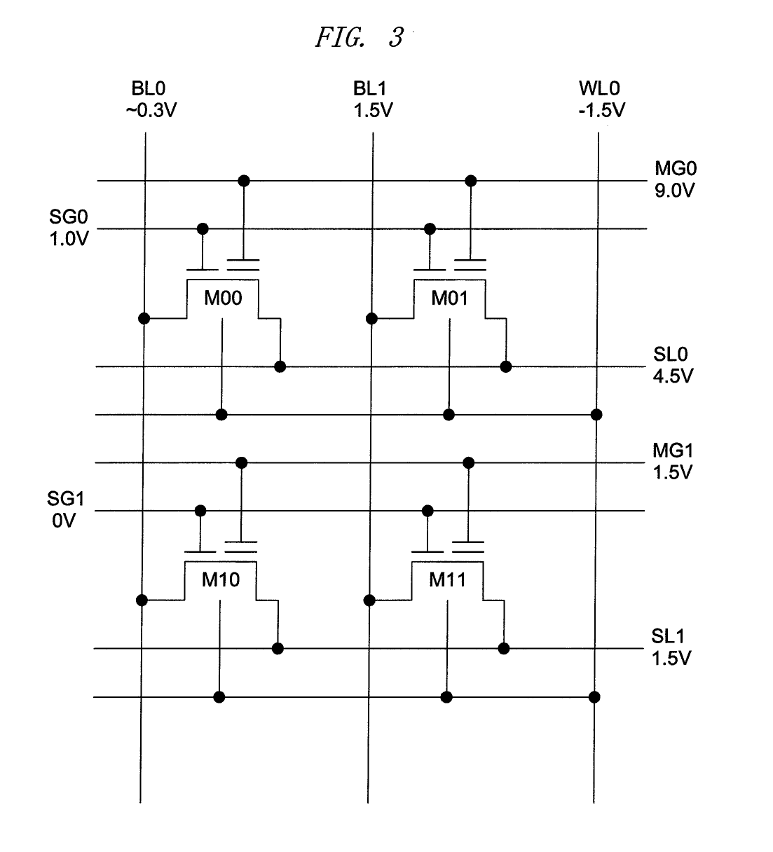

First, the writing operation will be described with reference to FIG. 3 and FIG. 2. FIG. 3 is an equivalent circuit diagram showing the voltage application conditions in the writing operation. Note that, for simplicity, FIG. 3 shows a part of the memory cell array 118 shown in FIG. 1, in other words, a memory cell array made up only of 2×2 memory cells (M00, M01, M10, M11). Moreover, the drawing also shows the voltages applied to the wiring when the memory cell M00 is selected to carry out the electron injection for writing.

The writing operation is carried out by the hot electron injection, so-called SSI writing method. More specifically, 4.5 V of the source line SL0 is applied to the source region 15S of the memory cell M00 selected for the write, and 9 V of the memory gate line MG0 is applied to the memory gate electrode 16. Moreover, 1.0 V of the select gate line SG0 is applied to the select gate electrode 17, and −1.5 V of the well line WL0 is applied to the p type well region 21.

The voltage applied to the bit line BL0 connected to the drain region 15D is controlled so that the channel current in the writing has a certain set value. For example, when the set current value is 1 μA, the voltage applied to the drain region 15D is about 0.2 V. The larger negative voltage is more preferable as the voltage applied to the p type well region 21, but the negative voltage can be increased only within the range allowed by the breakdown voltage of the gate insulating film 14 formed below the select gate electrode 17. When the breakdown voltage of the gate insulating film 14 is Vox and the voltage applied to the select gate electrode 17 in the writing is Vsg, the absolute value of the voltage applied to the p type well region 21 has to be Vox-Vsg or less.

Under the above-described voltage application conditions, the current which flows through the channel region of the memory cell M00 in the writing is determined by the difference in the electric potentials between the select gate electrode 17 and the drain region 15D and the threshold voltage of the select transistor. When the threshold voltage of the select transistor is varied, the channel current is varied, and the writing speed is correspondingly varied. For the suppression of the variations in the writing speed, it is preferable to automatically control the threshold voltage by means of the circuit configuration so as to achieve a constant channel current. For example, when the circuit method described in IEEE, VLSI Circuits Symposium 2003 Proceedings, pp. 211 to 212 is used, writing at a constant channel current can be carried out.

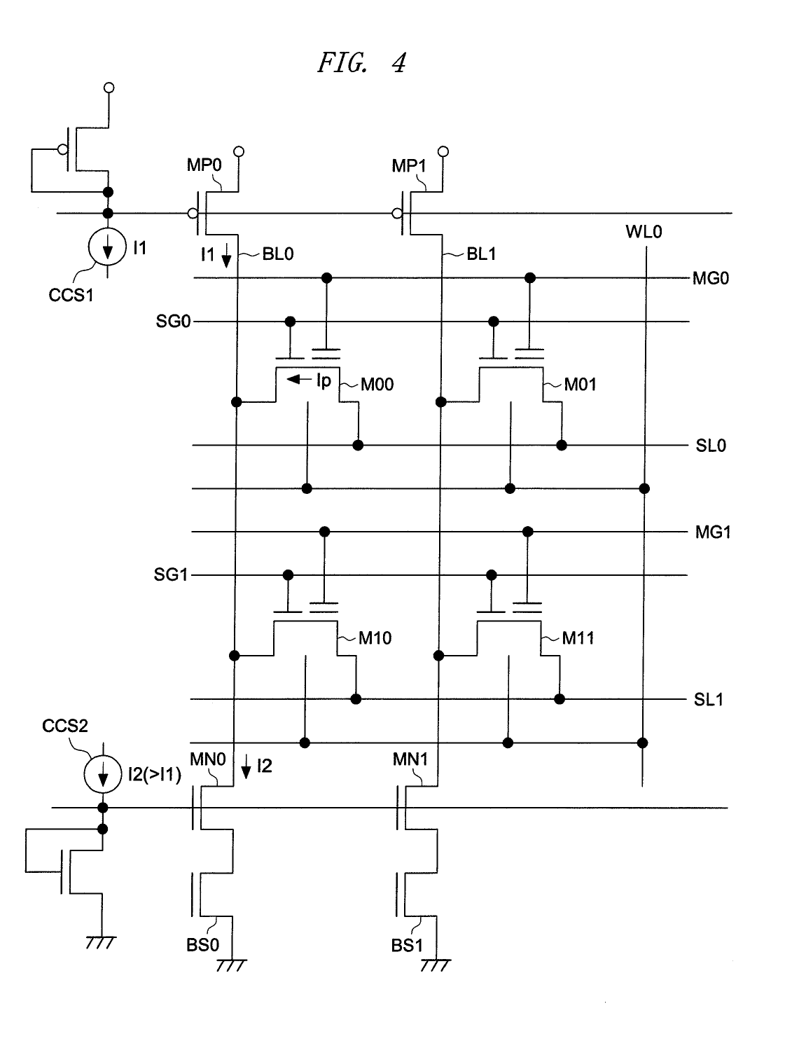

FIG. 4 shows an example of a circuit configuration which realizes the writing/erasing operations of the constant channel current. As shown in FIG. 4, mirror circuits made up of p channel MISFETs (MP0, MP1) are provided at one end portions of the bit lines BL0 and BL1, and mirror circuits made up of n-channel type MISFETs (MN0, MN1) are provided at the other end portions thereof.

Herein, the same voltages as the voltages shown in FIG. 3 are applied to the lines except for the bit lines BL0 and BL1. Furthermore, a current I1 is caused to flow to a constant current source CCS1, and a current I2 larger than the current I1 is caused to flow to a constant current source CCS2. Herein, when a bit-line select switching transistor BS0 of the bit line BL0 to which the memory cell M00 selected for write is connected is brought into an on state, the current I2 flows to the NMOS transistor MN0 from the bit line BL0 in the direction toward the earth by the principle of the mirror circuit, and the current I1 flows to the PMOS transistor MP0 in the direction toward the bit line BL0. The current of the difference between the current I2 and the current I1 is supplied to the bit line BL0 via only the memory cell M00 in which the select transistor is in the on state among the memory cells (M00, M10) connected to the bit line BL0. In other words, the current Ip (=I2−I1) flows to the channel region of the memory cell M00. In this manner, by setting the difference between the current I2 and the current I1 to the channel current value in the writing and bringing the bit-line select switching transistor BS0 into an inverted state, the writing can be carried out while causing the constant current (current Ip) to flow to the channel region of the memory cell M00 selected for write.

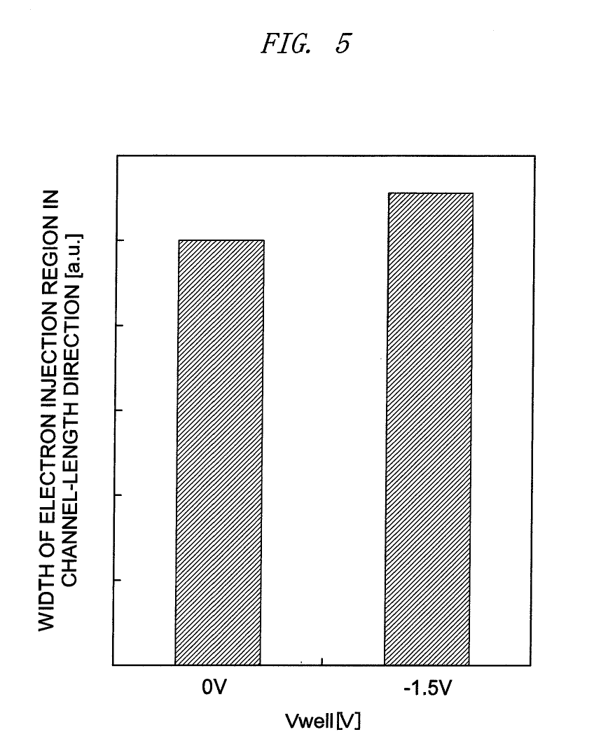

FIG. 5 shows the simulation results of the width of the electron injection region in the channel length direction (the direction in which a channel current flows) in the case where a negative voltage (−1.5 V) is applied to the p type well region 21 in the SSI writing and the case where no voltage (0 V) is applied thereto. The electron injection region is defined as a region having an injected electron density of 1.8×10¹⁹/cm³ or more. When the case where the voltage applied to the p type well region 21 is −1.5 V and the case where the voltage applied thereto is 0 V are compared with each other, it can be understood that the width of the electron injection region in the channel length direction is expanded by applying −1.5 V to the p type well region 21. This is because, when the negative voltage (−1.5 V) is applied to the p type well region 21, the electron potential of the channel part below the select gate electrode 17 is increased, the electric potential difference between the channel part below the select gate electrode 17 and the source region 15S is increased, and the electric field of the channel part in the channel length direction below the gap region between the select gate electrode 17 and the memory gate electrode 16 and below the memory gate electrode 16 is increased, and as a result, electrons are further accelerated in the channel direction and the electron distribution is expanded toward the source region 15S side.

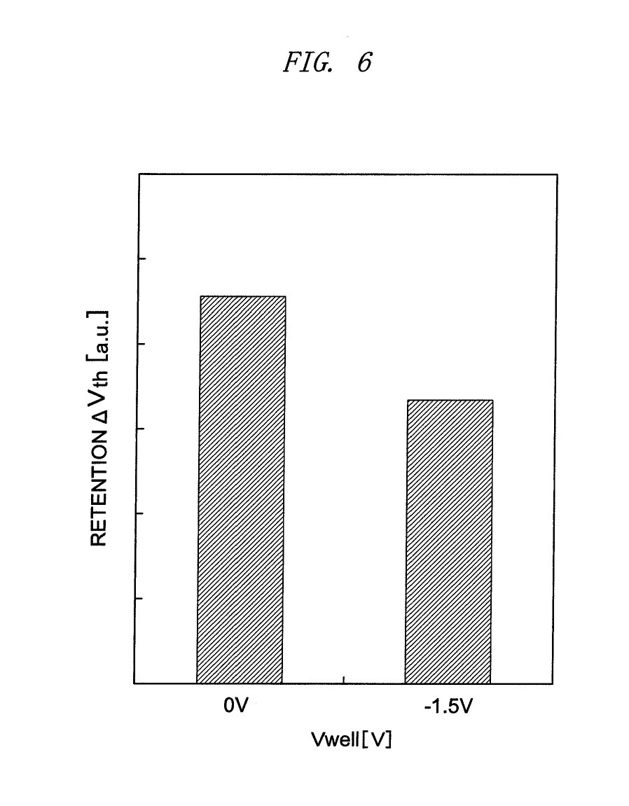

FIG. 6 is a graph showing the amount of the change in the threshold voltage after 10,000 seconds of retention in the erase state obtained after rewrite is carried out 10,000 times in the case where the negative voltage (−1.5 V) is applied to the p type well region 21 in the SSI writing and the case where no voltage (0 V) is applied thereto. Increase in the threshold voltage is suppressed in the case where the negative voltage is applied to the p type well region 21 than the case where the negative voltage is not applied to the p type well region 21. In other words, when the negative voltage is applied to the p type well region 21 in the SSI writing, the retention characteristics are improved. Since the electron injection distribution is expanded toward the source region 15S side by applying the negative voltage to the p type well region 21 in the writing, the holes and electrons existing locally and left behind due to the elimination failure that are caused with the rewriting are reduced, and as a result, the retention characteristics are improved.

Also when the voltage applied to the source region in the writing is increased, the electric field in the channel direction in the channel region of the gap part between the select gate electrode 17 and the memory gate electrode 16 is increased, and the injected electron distribution is expanded to the source region 15S side like in the case where the negative voltage is applied to the p type well region 21. However, when the voltage applied to the source region 15S in the writing is increased, the area of a charge pump circuit, which supplies a current to the source region 15S, has to be increased, and as a result, the chip area is increased.

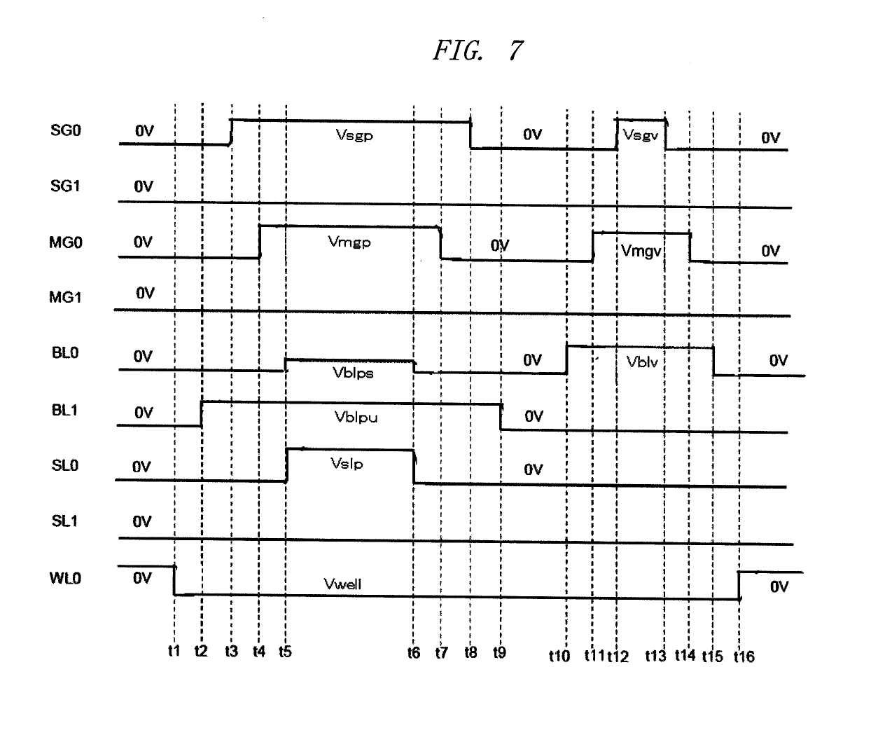

Subsequently, the timing of voltage application in the writing operation is shown in FIG. 7. FIG. 7 is a timing chart of the voltage application to each wiring in the case where the writing to the memory cell M00, which is selected for the write, is carried out in the memory cell array shown in FIG. 3. Moreover, FIG. 7 also shows the charge application timing of a verify read operation for confirming the threshold level after the write.

First, Vwell is applied to the well line WL0 at time t1, thereby causing the voltage of the p type well region 21 to be Vwell. Subsequently, the voltage of the non-selected bit line BL1 is increased to Vblpu at time t2. For example, Vwell is −1.5 V, and Vblpu is 1.5 V. FIG. 3 and FIG. 7 show the case where the non-selected memory gate line MG1 and the non-selected source line SL1 are at 0 V, but if a voltage is to be applied to the non-selected memory gate line MG1 or the non-selected source line SL1 so as to improve the write disturb characteristics, the voltage is applied thereto at the time t2. The order of applying the voltages is not particularly limited. More specifically, the voltage application to the p type well region 21 at the time t1 and the voltage application to the bit line BL1 at the time t2 may be carried out in a reverse order to that described above.

At time t3 and thereafter, voltages are applied to the wiring connected to the memory cell M00. More specifically, Vsgp is applied at the time t3 to the select gate line SG0 connected to the memory cell M00, Vmgp is applied at time t4 to the memory gate line MG0 connected to the memory cell M00, and Vslp is applied at time t5 to the source line SL0 connected to the memory cell M00. For example, Vsgp is 1 V, Vmgp is 9 V, and Vslp is 4.5 V. When the voltage is applied to the source line SL0, the channel current of the memory cell M00 starts to flow, and the voltage of the bit line BL0 connected to the drain region 15D of the memory cell M00 is increased so that the channel current has a desired current value set in advance. The order of applying the voltages to the memory cell M00 at the time t3, t4 and t5 is not particularly limited, but the order that does not deteriorate the write disturb resistance is preferred. In the period between the time t5 and the time t6, electron injection is carried out in the memory cell M00, and the electron injection is carried out for the time corresponding to the writing speed of the memory cell M00.

At time t6 and thereafter, the operations reverse to those carried out until the time t5 are carried out. More specifically, the voltage of the source line SL0 connected to the memory cell M00 is reduced to 0 V at the time t6. When the voltage of the source line SL0 is reduced, the channel current of the memory cell. M00 is reduced, and therefore, the electric potential of the bit line BL0 connected to the memory cell M00 is also reduced to 0 V. Next, the voltage of the memory gate line MG0 connected to the memory cell M00 is reduced to 0 V at time t7, and the voltage of the select gate line SG0 connected to the memory cell M00 is reduced to 0 V at time t8. The order of reducing the voltages of the selected memory cell to 0 V at the time t6, t7 and t8 is not particularly limited, but the order which does not deteriorate the write disturb resistance is preferred.

If writing of another memory cell connected to the same select gate line SG0, memory gate line MG0 and source line SL0 is to be subsequently carried out, the writing is continuously carried out without reducing the voltages. If writing of a memory cell connected to other select gate line, memory gate line and source line is to be continuously carried out, the voltage application to the select gate line, the memory gate line and the source line to which the memory cell is connected is continuously carried out. Then, after the series of writing operations is finished, the voltages of non-selected wiring are reduced except for the negative voltage of the well line WL0. In FIG. 7, the non-selected bit line BL1 is reduced to 0 V at time t9.

Next, a transition to the verify read operation is made while applying the negative voltage Vwell to the well line WL0. Herein, the memory cell M00 is subjected to verify read. Specifically, Vblv is applied at time t10 to the bit line BL0 connected to the memory cell M00, and Vmgv is applied at time t11 to the memory gate line MG0 connected to the memory cell M00. The voltage applied to the memory gate line MG0 connected to the memory cell M00 corresponds to the level of the threshold voltage of the write, and the voltage value is changed depending on the setting of the writing level. Subsequently, Vsgv is applied at time t12 to the select gate line SG0 connected to the memory cell M00. For example, Vblv is 1.0 V, Vmgv is 5.0 V, and Vsgv is 1.0 V. Then, the sense amplifier connected to the bit line BL0 is operated, and verify of the writing level of the memory cell M00 is carried out.

After the verify is finished, the voltage of the select gate SG0 connected to the memory cell M00 is reduced to 0 V at time t13, the voltage of the memory gate line MG0 connected to the memory cell M00 is reduced to 0 V at time t14, and the voltage of the bit line BL0 connected to the memory cell M00 is reduced to 0 V at time t15.

The verify read operation is finished in the manner described above. If the write level of the memory cell M00, for which the write has been carried out, has reached a desired level, the write is finished, and if not reached, the write and the verify read are repeated again. After all of the writing operations are finished, the voltage of the well line WL0 connected to the memory cell M00 is returned to 0 V at time t16.

The above-described verify read may be carried out under the same voltage conditions as those of a later-described normal read operation in which the voltage of the p type well region 21 is returned to 0 V. However, when the verify read is carried out while applying the negative voltage to the p type well region 21 as shown in FIG. 7, the time required for the whole writing operation can be shortened because the voltage applied to the p type well region 21 does not have to be increased and reduced every time the write and the verify read are repeated. Also, the writing operation can be carried out without the verify read. In such a case, however, there is the possibility that the sufficient write level is not reached in the memory cell in which write is slow and the reliability is deteriorated.

In the description of FIG. 7, the voltages applied in the writing and the verify read to the select gate line SG0 connected to the memory cell M00 are the same, but the voltages are not limited to these. In the verify read, the speed and accuracy are improved as the channel current becomes higher, and therefore, it is preferable that the magnitude of the voltage applied to the select gate line SG0 connected to the memory cell M00 is increased as much as possible within the range of the breakdown voltage of the select transistor.

Next, the erasing operation of the memory cell according to the present embodiment will be described. The erasing operation is carried out by the hot hole injection called BTBT erasing method.

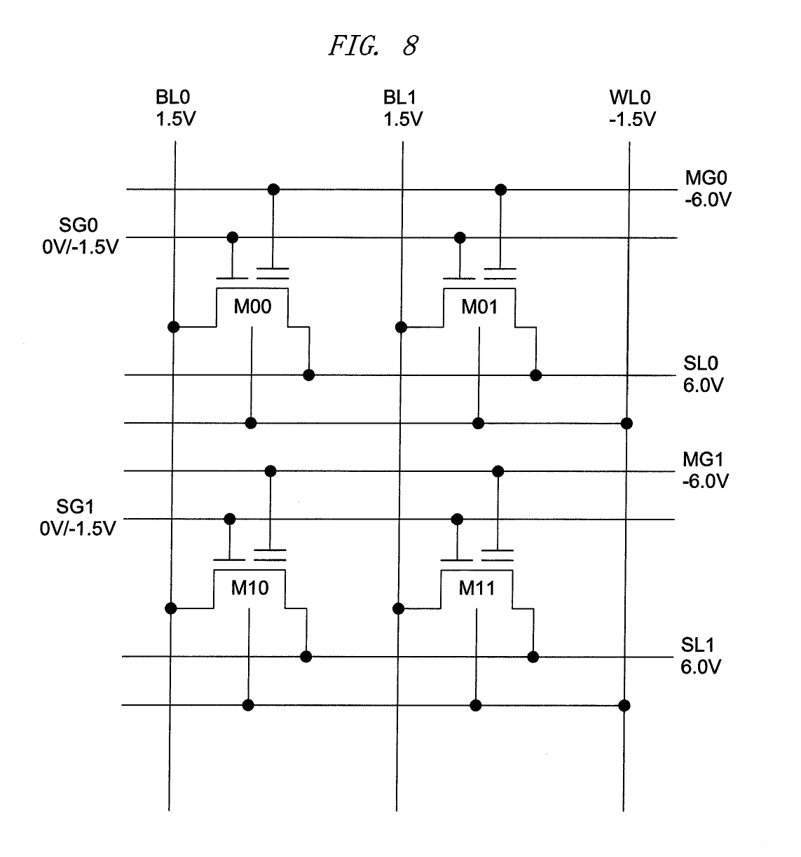

FIG. 8 is an equivalent circuit diagram showing the application conditions of the voltages in the erasing operation. Herein, for simplicity, the memory cell array made up only of 2×2 memory cells (M00, M01, M10, M11) is shown like FIG. 3. Moreover, the voltages applied to each wiring when all of the memory cells (M00, M01, M10, M11) are subjected to erase are also shown.

As shown by the application voltage conditions of FIG. 8, 6.0 V of the source lines SL0 and SL1 is applied to the source regions 15S of all of the memory cells, −6.0 V of the memory gate lines MG0 and MG1 is applied to the memory gate electrodes 16, 0 V or −1.5 V of the select gate lines SG0 and SG1 is applied to the select gate electrodes 17, and −1.5 V of the well line WL0 is applied to the p type well regions 21, respectively.

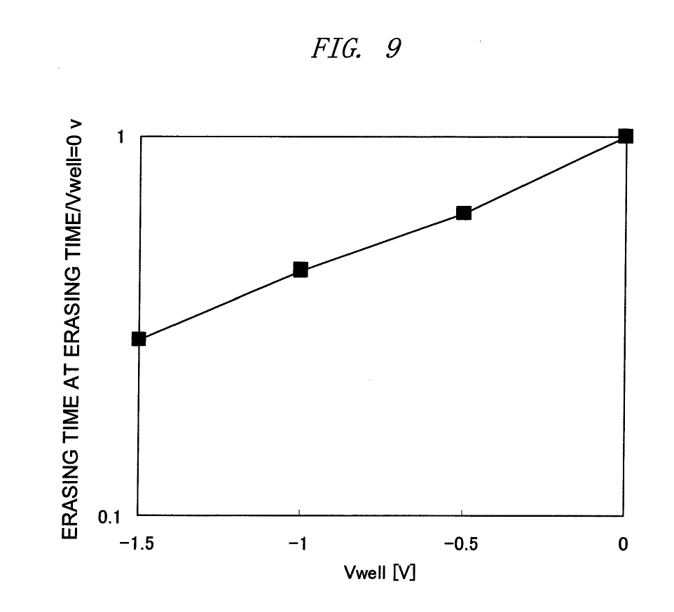

FIG. 9 is a graph showing the dependency of the erasing time with respect to the voltage applied to the p type well region 21. The erasing time is standardized by the erasing time at the point when the voltage applied to the p type well region 21 is 0 V. As is understood from FIG. 9, the erasing speed becomes faster as the negative voltage applied to the p type well region 21 becomes larger. In the BTBT erase, a positive high voltage (for example, 6.0 V) is applied to the source region 15S of the memory cell, and a negative high voltage (for example, −6.0 V) is applied to the memory gate electrode 16, thereby generating holes by the BTBT phenomenon at the end portion of the source region 15S. Then, the holes are accelerated by the electric field between the source region 15S and the p type well region 21, and the accelerated holes are pulled by the negative voltage of the memory gate electrode 16 and injected into the charge accumulating part (silicon nitride film 12). At this time, by increasing the negative voltage applied to the p type well region 21, the electric field generated by the positive high voltage of the source region 15S and the negative voltage of the p type well region 21 is increased, and the holes generated at the end portion of the source region 15S are accelerated by the high electric field, and therefore, the erasing speed can be increased.

Note that, also when the positive voltage applied to the source region 15S is increased, the erasing speed is increased because the electric field between the source region 15S and the p type well region 21 is increased. However, if the voltage applied to the source region 15S is increased, the area of the charge pump circuit which drives the source lines SL0 and SL1 and those of the driver and decoder of the source lines SL0 and SL1 are increased. On the other hand, when the negative voltage is applied to the p type well region 21, since the voltage applied to the source region 15S is not required to be increased, the erasing speed can be increased without increasing the area of the charge pump circuit which drives the source lines SL0 and SL1 and those of the driver and decoder of the source lines SL0 and SL1. Furthermore, since the erasing speed is increased, the voltage applied to the source region 15S can be reduced, and therefore, the area of the charge pump circuit which drives the source lines SL0 and SL1 and those of the driver and decoder of the source lines SL0 and SL1 can be reduced.

As described above, the erasing speed becomes faster as the negative voltage applied to the p type well region 21 becomes larger, but the negative voltage can be increased only within the range allowed by the breakdown voltage of the gate insulating film 14 below the select gate electrode 17. If the breakdown voltage of the gate insulating film 14 is Vox and the voltage applied to the select gate electrode 17 in the erasing is Vsg, the absolute value of the voltage applied to the p type well region 21 has to be Vox-Vsg or less. When the negative voltage is applied to the select gate electrode 17, a further larger negative voltage can be applied to the p type well region 21.

The above-described BTBT erase in which the negative voltage is applied to the p type well region 21 can obtain similar effects not only when it is applied to the split gate MONOS memory, but also when it is applied to a single gate MONOS memory.

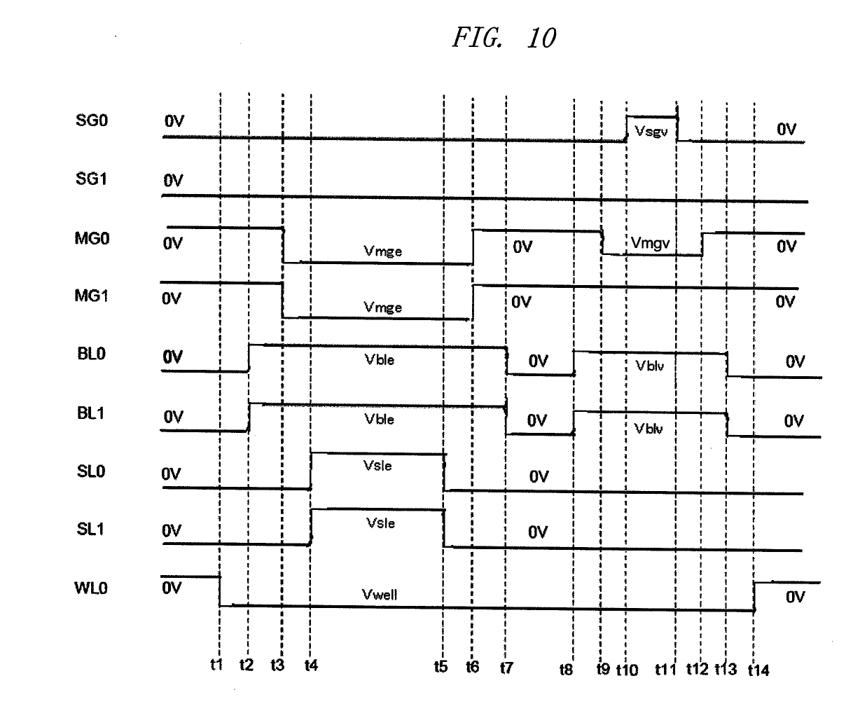

Subsequently, the timing of the voltage application in the erasing operation is shown in FIG. 10. FIG. 10 is a timing chart of the voltage application to each wiring in the case where all of the 2×2 memory cells (M00, m01, M10, M11) are to be subjected to erase in the memory cell array shown in FIG. 8. Moreover, FIG. 10 also shows the voltage application timing of a verify read operation for confirming the erasing level of the two memory cells (M00, M01).

First, Vwell is applied to the well line WL0 at time t1, thereby causing the voltage of the p type well region 21 to be Vwell. Subsequently, the voltages of the bit lines BL1 and BL0 are increased to Vble at time t2. The order of the voltage application of the well line WL0 and the voltage application of the bit lines BL1 and BL0 is not particularly limited. Next, Vmge is applied at time t3 to the memory gate lines MG0 and MG1 connected to the memory cells (M00, M01, M10, M11), and Vsle is applied at time t4 to the source lines SL0 and SL1 connected to the memory cells (M00, M01, M10, M11). For example, Vwell is −1.5 V, Vble is 1.5 V, Vmge is −6 V, and Vsle is 6 V. The order of the voltage application of the memory gate lines MG0 and MG1 and the voltage application of the source lines SL0 and SL1 is not particularly limited, but the order which does not deteriorate the erase disturb resistance is preferred.

In the period between the time t4 and the time t5, hole injection is carried out in the memory cells (M00, M01, M10, M11), and the hole injection is carried out for the time corresponding to the erasing speed of the memory cells (M00, M01, M10, M11).

Next, the voltages of the source lines SL0 and SL1 connected to the memory cells (M00, M01, M10, M11) are reduced to 0 V at time t5, and the voltages of the memory gate lines MG0 and MG1 connected to the memory cells (M00, M01, M10, M11) are changed to 0 V at time t6. The order of changing the voltages of the source lines SL0 and SL1 and the voltages of the memory gate lines MG0 and MG1 to 0 V is not particularly limited, but the order which does not deteriorate the erase disturb resistance is preferred. Subsequently, the bit lines BL0 and BL1 are reduced to 0 V at time t7.

Subsequent to the erasing operation, the verify read operation is carried out while applying the negative voltage Vwell to the well line WL0. Herein, an example in which the two memory cells (M00, M01) shown in FIG. 8 are subjected to verify read is described. First, Vblv is applied to the bit lines BL0 and BL1 at time t8, and Vmgv is applied at time t9 to the memory gate line MG0 connected to the memory cells (M00, M01). The voltage applied to the memory gate line MG0 corresponds to the level of the threshold voltage of the erase, and the voltage value is changed by the setting of the erasing level. Regarding the applied voltages, for example, Vblv is 1.0 V and Vmgv is −2.0 V.

Next, 1.0 V is applied at time t10 to the select gate line SG0 also connected to the memory cells (M00, M01). Then, the sense amplifier (SA) connected to the bit lines BL0 and BL1 is operated, and verify of the erasing levels of the memory cells (M00, M01) is carried out. After the verify is finished, the voltage of the select gate SG0 connected to the memory cells (M00, M01) is reduced to 0 V at time t11. Subsequently, the voltage of the memory gate line MG0 connected to the memory cells (M00, M01) is reduced to 0 V at time t12, and then, the voltages of the bit lines BL0 and BL1 connected to the memory cells (M00, M01) are reduced to 0 V at time t13. Although not shown in FIG. 10, the verify read of the other memory cells (M10, M11), which have been subjected to the erase, is subsequently executed in the same manner as described above.

When the verify read operations of the memory cells (M00, M01, M10, M11), which have been subjected to the erase, are finished, if the erasing level has reached a desired level, the erasing operation is finished, and if not reached, the erase and verify read are repeated again. After all of the erasing operations are finished, the voltage of the well line WL0 is returned to 0 V at time t14.

The above-described verify read may be carried out under the same voltage conditions as those of a later-described normal read operation in which the voltage of the p type well region 21 is returned to 0 V. However, when the verify read is carried out while applying the negative voltage to the p type well region 21 as shown in FIG. 10, the time required for the whole erasing operation can be shortened because the voltage applied to the p type well region 21 does not have to be increased and reduced every time the erase and the verify read are repeated. Also, the erasing operation can be carried out without the verify read. In such a case, however, there is the possibility that the sufficient erasing level is not reached in the memory cell in which erase is slow and the reliability is deteriorated.

Regarding the writing method and the erasing method of the present embodiment described above, either one of the writing method and the erasing method may be used and carried out in combination with a conventional SSI writing method or a conventional BTBT method, or both of them may be used. When a conventional method is used for write or erase, the time required for the voltage application of the p type well region 21 becomes unnecessary. If both of the writing method and the erasing method of the present embodiment are used, since the effects of both of them can be achieved by a common power supply, driver and decoder of the p type well region 21, increase in the chip area can be suppressed. Furthermore, if the negative voltage applied to the p type well region 21 in the writing and the negative voltage applied to the p type well region 21 in the erasing are made equal to each other, since the number of power supplies can be reduced, the area of a power supply circuit can be reduced.

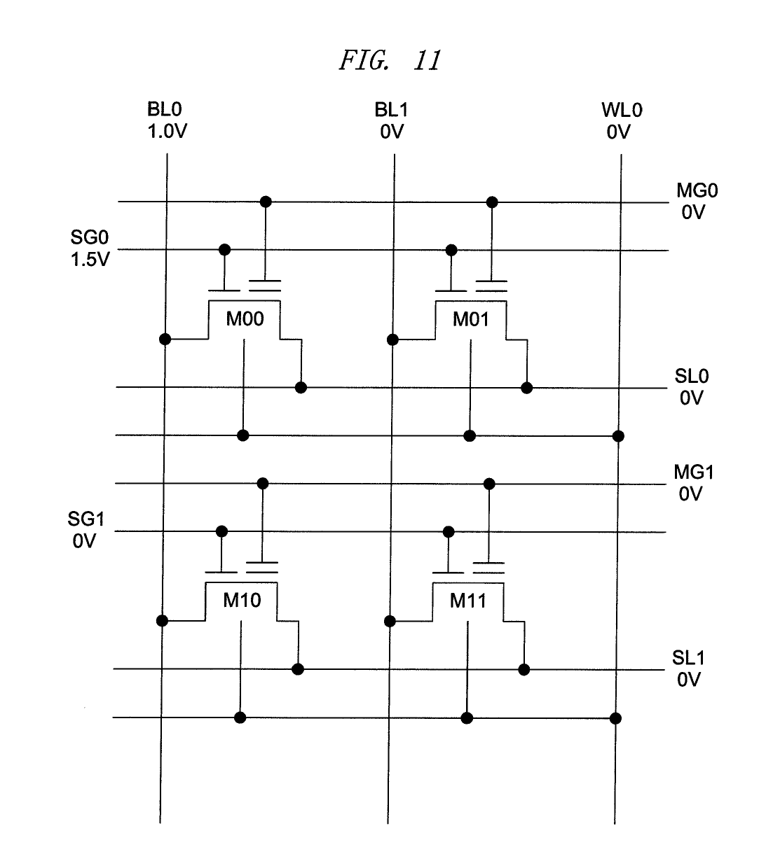

Next, the reading operation of the memory cell according to the present embodiment will be described. FIG. 11 is an equivalent circuit diagram showing the voltage application conditions in the reading operation. Herein, FIG. 11 shows the voltages applied to each wiring in the case where the memory cell M00 is read in the memory cell array made up only of 2×2 memory cells (M00, M01, M10, M11) like the writing operation described above.

As shown in the voltage application conditions of FIG. 11, unlike the writing operation and the erasing operation, no voltage is applied to the p type well region 21 in the reading operation. This is for the purpose of enabling the return from a standby state in an extremely short period of time to carry out the reading operation. The voltage of 1.0 V is applied to the bit line BL0 connected to the drain region 15S of the memory cell M00 to which the read is to be carried out, 1.5 V is applied to the select gate line SG0 connected to the select gate electrode 17, and the sense amplifier (SA) connected to the bit line BL0 is operated, thereby reading the data of the memory cell M00. 0 V is applied to the non-selected bit line BL1, the non-selected gate line SG1, all of the source lines SL0 and SL1 and all of the memory gate lines MG0 and MG1. If a larger reading voltage is required for carrying out high-speed reading, for example, 1.5 V may be applied to the memory gate lines MG0 and MG1.

### Second Embodiment

Generally, in a microcontroller, it is conceivable to integrate a plurality of non-volatile memory modules not only for increasing the integration degree of memory cells, but also for various purposes.

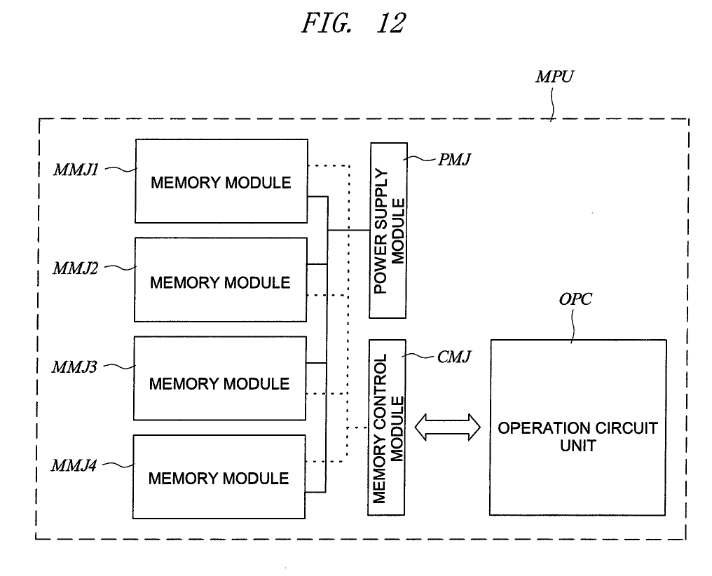

FIG. 12 is a block diagram schematically showing a semiconductor chip MPU formed by integrating a plurality of non-volatile memory modules MMJ1 to MMJ4 and others. In the semiconductor chip MPU shown in FIG. 12, the plurality of non-volatile memory modules MMJ1 to MMJ4, a memory control module CMJ for controlling the non-volatile memory modules MMJ1 to MMJ4, a power supply module PMJ for supplying predetermined electric potentials to the non-volatile memory modules MMJ1 to MMJ4 and an operation circuit unit OPC are integrated.

When the plurality of non-volatile memory modules MMJ1 to MMJ4 are integrated in one semiconductor chip MPU in this manner, it is conceivable that the uses of the memory cells in the respective modules MMJ1 to MMJ4 are different.

In the present embodiment, the operating characteristics of the non-volatile memory modules MMJ1 to MMJ4 can be changed without changing the memory cell structures thereof. Therefore, among the plurality of non-volatile memory modules MMJ1 to MMJ4 integrated in the single semiconductor chip MPU, the methods (writing method and erasing method) of the above-described first embodiment can be applied only to the required non-volatile memory modules, and the other non-volatile memory modules can be operated by conventional methods (writing method and erasing method). In other words, it is possible to apply the writing method and the erasing method of the first embodiment only to the required non-volatile memory modules, and at the same time, the non-volatile memory modules operated in a conventional manner can be integrated on the single semiconductor chip MPU. Specifically, the writing method of the first embodiment is applied only to the modules used under the conditions in which higher retention characteristics are required, and the erasing method of the first embodiment is applied only to the modules used under the conditions in which a higher erasing speed is required. By this means, increase in the circuit area of a substrate bias application circuit and others can be suppressed to a minimum level, and the effects of retention characteristic improvement or erasing speed improvement can be achieved.

In the foregoing, the invention made by the inventors of the present invention has been concretely described based on the embodiments. However, it is needless to say that the present invention is not limited to the foregoing embodiments and various modifications and alterations can be made within the scope of the present invention.

For example, in the above-described embodiments, the silicon nitride film (charge trapping insulating film) is used as the charge accumulating film of the memory cell, but a charge trapping insulating film such as a silicon oxynitride film, a tantalum oxide film, an aluminum oxide film or the like can be used instead of the silicon nitride film. A conductive material such as polycrystalline silicon or fine particles (dots) made of a conductive material may be used as the charge accumulating layer. Furthermore, the memory transistor and the select transistor constituting the memory cell may be composed of p channel MIS transistors.

The present invention can be applied to a non-volatile semiconductor storage device having a split gate MONOS memory.

What is claimed is:

1. A non-volatile semiconductor storage device comprising:
a plurality of non-volatile memory cells formed in a first region of a semiconductor substrate; and
a drive circuit formed in a second region of the semiconductor substrate,
wherein each of the plurality of memory cells has:
(a) first and second semiconductor regions formed in the semiconductor substrate;
(b) a first conductive layer and a second conductive layer formed on the semiconductor substrate between the first and second semiconductor regions, the first conductive layer being positioned on a first semiconductor region side, the second conductive layer being positioned on a second semiconductor region side;
(c) a first insulating film formed between the first conductive layer and the semiconductor substrate; and
(d) a charge accumulating region made of a second insulating film formed between the second conductive layer and the semiconductor substrate,
the drive circuit controls voltages applied to the first region of the semiconductor substrate, the first semiconductor region, the second semiconductor region, the first conductive layer and the second conductive layer, thereby carrying out a writing operation by hot electron injection using a source side injection method and carrying out an erasing operation by a hot hole injection method utilizing a band-to-band tunneling phenomenon, and
a negative voltage is applied to the first region of the semiconductor substrate in the writing operation.

2. The non-volatile semiconductor storage device according to claim 1,
wherein the first region and the second region of the semiconductor substrate are electrically separated from each other, and the drive circuit is connected to the second region.

3. The non-volatile semiconductor storage device according to claim 1,
wherein a third region having a conductivity type different from the first region and the second region is provided in the semiconductor substrate between the first region and the second region.

4. The non-volatile semiconductor storage device according to claim 1,
wherein a negative voltage application circuit is connected to the second region of the semiconductor substrate.

5. The non-volatile semiconductor storage device according to claim 1,
wherein the second insulating film constituting the charge accumulating region is a silicon nitride film sandwiched by two silicon oxide films.

6. The non-volatile semiconductor storage device according to claim 1,
wherein the drive circuit applies a negative voltage to the first region of the semiconductor substrate in verify read after the hot electron injection in the writing operation.

7. The non-volatile semiconductor storage device according to claim 1,
wherein the drive circuit applies a negative voltage to the first region of the semiconductor substrate in the erasing operation.

8. The non-volatile semiconductor storage device according to claim 5,
wherein the drive circuit applies a positive voltage to the second semiconductor region and the second conductive layer in the erasing operation.

9. A non-volatile semiconductor storage device comprising:
a plurality of non-volatile memory cells formed in a first region of a semiconductor substrate; and
a drive circuit formed in a second region of the semiconductor substrate,
wherein each of the plurality of memory cells has:
(a) first and second semiconductor regions formed in the semiconductor substrate;
(b) a conductive layer formed on the semiconductor substrate between the first and second semiconductor regions; and
(c) a first insulating film formed between the conductive layer and the semiconductor substrate, and
the drive circuit applies a negative voltage to the first region of the semiconductor substrate, applies a positive voltage to the second semiconductor region, and applies a negative voltage to the conductive layer in an erasing operation.

10. The non-volatile semiconductor storage device according to claim 9,
wherein the first region and the second region of the semiconductor substrate are electrically separated from each other, and the drive circuit is connected to the second region.

11. The non-volatile semiconductor storage device according to claim 9,
wherein a third region having a conductivity type different from the first region and the second region is provided in the semiconductor substrate between the first region and the second region.

12. The non-volatile semiconductor storage device according to claim 9,
wherein a negative voltage application circuit is connected to the second region of the semiconductor substrate.

13. The non-volatile semiconductor storage device according to claim 12,
wherein the erasing operation is carried out by a hot hole injection method utilizing a band-to-band tunneling phenomenon.
